(19) United States
(12) Patent Application Publication
(10) Pub. No.: US 2018/0254182 A1
(43) Pub. Date: Sep. 6, 2018

(54) SURFACE TREATMENT METHOD AND SURFACE TREATMENT LIQUID

(71) Applicant: Tokyo Ohka Kogyo Co., Ltd., Kanagawa (JP)

(72) Inventors: Yuriko SHIRAI, Kanagawa (JP); Daijiro MORI, Kanagawa (JP); Akira KUMAZAWA, Kanagawa (JP)

(73) Assignee: Tokyo Ohka Kogyo Co., Ltd., Kanagawa (JP)

(21) Appl. No.: 15/909,183

(22) Filed: Mar. 1, 2018

(30) Foreign Application Priority Data
Mar. 2, 2017 (JP) 2017-039819

(51) Int. Cl. H01L 21/027; H01L 21/308; C09K 3/18

(52) U.S. Cl. CPC H01L 21/0273; C09K 3/18; H01L 21/3081

(57) ABSTRACT

To provide a surface treatment method capable of highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride, and also provide a surface treatment liquid suitably used for the surface treatment method. A surface treatment liquid used for the surface treatment method includes a silylating agent (A) and a solvent (S), the silylating agent (A) does not have an alkoxy group bonded to a silicon atom, and the solvent (S) does not have a hydroxyl group bonded to a carbon atom. A value of dH in Hansen solubility parameters (HSP) in the solvent (S) is 3.2 MPa^{1/2} or less or 10.5 MPa^{1/2} or more. Relative Energy Difference represented by Rₐ/R₀ is 1.2 or more, where the interaction radius of polyvinyl chloride in the Hansen space is defined as R₀ and a distance between the HSP of the polyvinyl chloride and HSP of the solvent (S) is defined as Rₐ.

This application is based on and claims the benefit of priority from Japanese Patent Application No. 2017-039819, filed on 2 Mar. 2017, the content of which is incorporated herein by reference.

### BACKGROUND OF THE INVENTION

### Field of the Invention

The present invention relates to a surface treatment method and a surface treatment liquid.

### Related Art

In recent years, trends toward higher integration and miniaturization of semiconductor devices have grown, and thus progress toward refinement and higher aspect ratios of a resin pattern as an etching mask in etching a substrate and an inorganic pattern produced by etching processes have advanced. In the meantime, however, a problem of so-called pattern collapse has arisen. This pattern collapse is a phenomenon in which when several resin patterns or inorganic patterns are formed on a substrate in parallel, adjacent patterns close in so as to lean on one another, and the patterns are damaged and peeled off from the base depending on the situation. Occurrence of such pattern collapse causes a decline in the yield and reliability of the product.

This pattern collapse is known to occur when drying a cleaning liquid in a cleaning process after pattern formation, due to the surface tension of this cleaning liquid. In other words, when the cleaning liquid is removed in a drying step, stress based on the surface tension of the cleaning liquid has an effect between patterns, whereby pattern collapse occurs.

Conventionally, using a surface treatment liquid including silylating agents such as N,N-dimethylaminotrimethylsilane (TMSDMA) and hexamethyl disilazane (HMDS) and a solvent, the surface of a resin pattern or an inorganic pattern are hydrophobized (silylated) so as to prevent pattern collapse has been proposed (refer to, for example, Patent Document 1).

In addition, although not the same as pattern collapse, in order to improve adhesion between the resin pattern as the etching mask and the substrate to prevent a partial loss of the resin pattern by a developing solution, hydrophobization (silylation) of the substrate using silylating agents such as hexamethyl disilazane (HMDS) has been being performed on the surface of the substrate (refer to, for example, “Background Art” of Patent Document 2).

Incidentally, some devices to be used for washing or surface treatment of a substrate and the like are provided with a member made of polyvinyl chloride in a portion thereof (liquid contact portion) that is brought into contact with a cleaning liquid or a surface treatment liquid. However, when a surface treatment liquid containing the above-mentioned silylating agent is brought into contact with the member made of polyvinyl chloride, polyvinyl chloride may be deteriorated by the solvent contained in the surface treatment liquid.

Under such circumstances, Patent Document 3 proposes a surface treatment liquid (a drug solution for forming water repellent protective film) including specific monoalkoxysilane, specific sulfonic acid, and a dilution solvent, wherein the dilution solvent includes 80 to 100% by mass of alcohol relative to 100% by mass of the total amount of dilution solvent. The surface treatment liquid of Patent Document 3 enables the surface of a treatment target to be hydrophobized while the deterioration of polyvinyl chloride is suppressed.
Patent Document 1: Japanese Unexamined Patent Application, Publication No. 2010-129932
Patent Document 2: Japanese Unexamined Patent Application (Translation of PCT Application), Publication No. H11-511900
Patent Document 3: Japanese Unexamined Patent Application, Publication No. 2016-66785

### SUMMARY OF THE INVENTION

Conventionally, as a silylating agent having excellent hydrophobization (silylation) effect, N,N-dimethylaminotrimethylsilane (TMSDMA), hexamethyl disilazane (HMDS), and the like, have been known. The present inventors have studied the use of silylating agents such as N,N-dimethylaminotrimethylsilane (TMSDMA) and hexamethyl disilazane (HMDS) instead of the specific monoalkoxysilane in the surface treatment liquid of Patent Document 3. However, it is revealed that since the surface treatment liquid described in Patent Document 3 has high percentage content of alcohol, alcohol and the silylating agent are reacted with each other, thus remarkably deteriorating a hydrophobization effect.

The present invention has been made in view of the above problems. An object of the present invention is to provide a surface treatment method capable of highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride. Another object of the present invention is to provide a surface treatment liquid suitably used for such a surface treatment method.

In order to solve the abovementioned problems, the present inventors have conducted extensive studies. As a result, they have found that use of a surface treatment liquid combining a silylating agent and a specific solvent solves the above-mentioned problems, and have completed the present invention. More specifically, the present invention provides the following.

A first aspect of the present invention is a surface treatment method that treats a surface of a treatment target using a device having a liquid contact portion provided with a member made of polyvinyl chloride. The method includes bringing a surface treatment liquid into contact with a surface of the treatment target. The surface treatment liquid includes a silylating agent (A) and a solvent (S), the silylating agent (A) does not have an alkoxy group bonded to a silicon atom, and the solvent (S) does not have a hydroxyl group bonded to a carbon atom. A value of dH in the Hansen solubility parameters of the solvent (S) is 3.2 MPa^{1/2} or less or 10.5 MPa^{1/2} or more. Relative Energy Difference represented by Rₐ/R₀ is 1.2 or more where the interaction radius of the polyvinyl chloride in the Hansen space is defined as R₀, and a distance between the Hansen solubility parameters of the polyvinyl chloride and Hansen solubility parameters of the solvent (S) is defined as Rₐ.

A second aspect of the present invention is a surface treatment liquid to be used for surface treatment of a treatment target. The surface treatment liquid includes a silylating agent (A) and a solvent (S). The silylating agent (A) does not have an alkoxy group bonded to a silicon atom, and the solvent (S) does not have a hydroxyl group bonded to a carbon atom. The surface treatment liquid includes an alkoxysilane compound represented by the following Formula (S1):

SiR^{s1}₍₄₋ₐ₎R^{s2}ₐ (S1)

(in the Formula (S1), R^{s1} represents an alkoxy group having 1 to 4 carbon atoms, R^{s2} represents an alkyl group having 1 to 4 carbon atoms, and a represents an integer of 0 to 3).

A third aspect of the present invention is a surface treatment method that treats a surface of a treatment target. The method includes bringing a surface treatment liquid into contact with the surface of the treatment target. The surface treatment liquid includes a silylating agent (A) and a solvent (S). The silylating agent (A) does not have an alkoxy group bonded to a silicon atom, and the solvent (S) does not have a hydroxyl group bonded to a carbon atom, and includes an alkoxysilane compound represented by the following Formula (S1):

SiR^{s1}₍₄₋ₐ₎R^{s2}ₐ (S1)

(in the Formula (S1), R^{s1} represents an alkoxy group having 1 to 4 carbon atoms, R^{s2} represents an alkyl group having 1 to 4 carbon atoms, and a represents an integer of 0 to 3).

The present invention provides a surface treatment method capable of highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride. Also, the present invention provides a surface treatment liquid suitably used for such a surface treatment method.

### DETAILED DESCRIPTION OF THE INVENTION

### <First Surface Treatment Liquid>

A first surface treatment liquid in accordance with this exemplary embodiment is a surface treatment liquid to be used for a surface treatment of a treatment target using a device having a liquid contact portion provided with a member made of polyvinyl chloride. The surface treatment liquid includes a silylating agent (A) and a solvent (S), the silylating agent (A) does not have an alkoxy group bonded to a silicon atom, and the solvent (S) does not have a hydroxyl group bonded to a carbon atom. A value of dH in Hansen solubility parameters of the solvent (S) is 3.2 MPa^{1/2} or less or 10.5 MPa^{1/2} or more. Relative Energy Difference represented by Rₐ/R₀ is 1.2 or more where the interaction radius of the polyvinyl chloride in the Hansen space (polyvinyl chloride to be used for the liquid contact portion. Hereinafter, the same is true to the first surface treatment liquid.) is defined as R₀, and a distance between the Hansen solubility parameters of the polyvinyl chloride and Hansen solubility parameters of the solvent (S) is defined as Rₐ.

Such a first surface treatment liquid permits highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride.

A device for surface treatment of a treatment target is not particularly limited as long as the device can provide a surface treatment liquid to a treatment target. Examples of such a device include a device capable of providing surface treatment liquid to a treatment target by a spray method, a spin coating method, a dipping method, or the like. Furthermore, the liquid contact portion is not particularly limited as long as the portion is brought into contact with the surface treatment liquid. Examples thereof include a tank in which a surface treatment liquid is stored, a pipe through which a surface treatment liquid passes, a nozzle from which a surface treatment liquid is discharged, or the like.

Examples of the treatment target that is the target of surface treatment include a substrate to be used for manufacturing semiconductor devices. Surfaces of the treatment target include a surface of the substrate itself, as well as surfaces of an inorganic pattern and a resin pattern provided on a substrate, as well as surfaces of an inorganic layer and an organic layer that have not been patterned.

Examples of the inorganic pattern provided on the substrate include an inorganic pattern that has been formed by producing an etching mask on the surface of the inorganic layer present on the substrate by way of a photoresist method, and subsequently performing an etching process. Examples of the inorganic layer other than the substrate itself include a layer made of oxide of an element constituting the substrate, and a layer made of inorganic matter such as silicon nitride, titanium nitride, and tungsten, formed on the surface of the substrate. Although such an organic layer is not particularly limited, an inorganic layer that is formed in a manufacturing process of a semiconductor device is exemplified.

Examples of the resin pattern provided on the substrate include a resin pattern formed on the substrate by way of a photoresist method. Such a resin pattern is formed, for example, by forming an organic layer, which is a layer of photoresist, on the substrate, exposing this organic layer through a photomask, and developing. As the organic layer, in addition to the surface of the substrate itself, an organic layer that is provided on the surface or the like of a laminated film provided on the surface of the substrate is exemplified. Although such an organic layer is not particularly limited, an organic layer provided in order to form an etching mask in a manufacturing process of a semiconductor device is exemplified.

Hereinafter, essential or arbitrary components included in the first surface treatment liquid will be described.

### [Silylating Agent (A)]

A silylating agent included in a first surface treatment liquid is not particularly limited as long as it does not have an alkoxy group bonded to a silicon atom. Examples of the silylating agent include a silylating agent represented by the following Formulae (1) to (8) and a cyclic silazane compound.

### (Silylating Agent Represented by Formula (1))

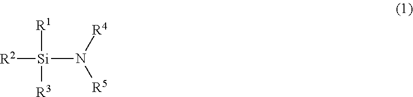

In the above Formula (1), R¹, R², and R³ each independently represent a hydrogen atom, a halogen atom, or an organic group. The sum of the carbon atoms of the R¹, R², and R³ is 1 or more. R⁴ represents a hydrogen atom or a saturated or unsaturated chain hydrocarbon group. R⁵ represents a hydrogen atom, a saturated or unsaturated chain hydrocarbon group, a saturated or unsaturated non-aromatic cyclic hydrocarbon group, or a non-aromatic heterocyclic group. R⁴ and R⁵ may be connected to each other to form a ring structure having a nitrogen atom.

In the case of R¹, R², or R³ being halogen atoms, as the halogen atom, a chlorine atom, a bromine atom, an iodine atom, and a fluorine atom are preferable.

In the case of R¹, R², or R³ being organic groups, the organic groups may include hetero atoms such as a nitrogen atom, an oxygen atom, and a sulfur atom in addition to a carbon atom. In the case of R¹, R², or R³ being organic groups, the sum of the number of the carbon atoms and the number of the hetero atoms which are included in the organic groups is not particularly limited as long as the sum of the number of carbon atoms of the R¹, R², and R³ is 1 or more. In the case of R¹, R², or R³ being organic groups, the sum of the number of the carbon atoms and the number of the hetero atoms which are included in the organic groups is preferably 1 to 10, more preferably 1 to 8, and still more preferably 1 to 3. In the case of R¹, R², or R³ being organic groups, a saturated or unsaturated chain hydrocarbon group, an aralkyl group, and an aromatic hydrocarbon group are preferable as the organic groups. Suitable examples of the saturated or unsaturated chain hydrocarbon group may include a methyl group, an ethyl group, a vinyl group, an n-propyl group, an isopropyl group, an allyl group, a 1-propenyl group, an isopropenyl group, an n-butyl group, a sec-butyl group, a tert-butyl group, a 3-butenyl group, an n-pentyl group, an isopentyl group, a sec-pentyl group, a tert-pentyl group, an n-hexyl group, an n-heptyl group, an n-octyl group, an n-nonyl group and an n-decyl group. Among these chain hydrocarbon groups, a methyl group, an ethyl group, a vinyl group, an n-propyl group, and an allyl group are more preferable, and a methyl group, an ethyl group, and a vinyl group are still more preferable. Suitable examples of the aralkyl group may include a benzyl group, a phenyl ethyl group, a phenyl propyl group, an α-naphthyl methyl group and a β-naphthyl methyl group. Suitable examples of the aromatic hydrocarbon group may include a phenyl group, an α-naphthyl group, and a β-naphthyl group.

In the case of R⁴ being a saturated or unsaturated chain hydrocarbon group, the number of carbon atoms of the saturated or unsaturated chain hydrocarbon group is not particularly limited. In the case of R⁴ being a saturated or unsaturated chain hydrocarbon group, the number of carbon atoms of the saturated or unsaturated chain hydrocarbon group is preferably 1 to 10, more preferably 1 to 8, and still more preferably 1 to 3. Suitable examples of R⁴ being a saturated or unsaturated chain hydrocarbon group are the same as saturated or unsaturated chain hydrocarbon groups exemplified as suitable groups for R¹, R², and R³.

In the case of R⁵ being a saturated or unsaturated chain hydrocarbon group, the saturated or unsaturated chain hydrocarbon group is the same as R⁴. In the case of R⁵ being a saturated or unsaturated cyclic hydrocarbon group, the number of carbon atoms of the saturated or unsaturated cyclic hydrocarbon group is not particularly limited. In the case of R⁵ being a saturated or unsaturated non-aromatic cyclic hydrocarbon group, the number of carbon atoms of the saturated or unsaturated non-aromatic cyclic hydrocarbon group is preferably 3 to 10, more preferably 3 to 6, and still more preferably 5 or 6. Suitable examples of R⁵ being a saturated or cyclic hydrocarbon group include a cyclopropyl group, a cyclobutyl group, a cyclopentyl group, a cyclohexyl group, a cyclopentyl group, and a cyclooctyl group. In the case of R⁵ being a non-aromatic heterocyclic group, the hetero atom included in the non-aromatic heterocyclic group is not particularly limited. In the case of R⁵ being a non-aromatic heterocyclic group, the sum of the number of the hetero atoms and the number of the carbon atoms included in the non-aromatic heterocyclic group is not particularly limited. In the case of R⁵ being a non-aromatic heterocyclic group, the sum of the number of the hetero atoms and the number of the carbon atoms included in the non-aromatic heterocyclic group is preferably 3 to 10, more preferably 3 to 6, and still more preferably 5 or 6. Suitable examples of R⁵ being a non-aromatic heterocyclic group include a pyrrolidin-1-yl group, a piperidine-1-yl group, a piperazine-1-yl group, a morpholine-1-yl group, and a thiomorpholine-1-yl group.

The number of the atoms included in the ring structure formed by binding R⁴ and R⁵ to each other is not particularly limited. The ring structure formed by binding R⁴ and R⁵ to each other is preferably a 3-membered ring to a 10-membered ring and more preferably a 5-membered ring or a 6-membered ring. The ring structure formed by binding R⁴ and R⁵ to each other may include an oxygen atom, a sulfur atom, and the like, that is, hetero atoms other than a nitrogen atom. Suitable examples of the ring structure formed by binding R⁴ and R⁵ to each other may include non-aromatic heterocycles such as pyrrolidine, piperidine, piperazine, morpholine and thiomorpholine, and aromatic heterocycles such as imidazole and triazol.

Specific examples of a silylating agent represented by the above Formula (1) may include N,N-dimethylamino trimethyl silane, N,N-dimethylamino dimethyl silane, N,N-dimethylamino monomethyl silane, N,N-diethylamino trimethyl silane, tert-butyl amino trimethyl silane, allyl amino trimethyl silane, trimethylsilyl acetamide, N,N-dimethylamino dimethyl vinyl silane, N,N-dimethylamino dimethyl propyl silane, N,N-dimethylamino dimethyl octyl silane, N,N-dimethylamino dimethyl phenylethyl silane, N,N-dimethylamino dimethyl phenyl silane, N,N-dimethylamino dimethyl-tert-butyl silane, N,N-dimethylamino triethyl silane and trimethyl silanamine, monomethylsilyl imidazole, dimethylsilyl imidazole, trimethylsilyl imidazole, monomethylsilyl triazol, dimethylsilyl triazol, trimethylsilyl triazol, and the like.

### (Silylating Agent Represented by Formula (2))

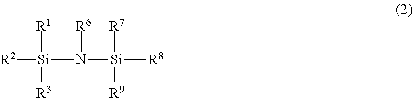

In the above Formula (2), R¹, R², and R³ are the same as in the above Formula (1). R⁶ represents a hydrogen atom, a methyl group, a trimethyl silyl group, or a dimethyl silyl group. R⁷, R⁸, and R⁹ each independently represent a hydrogen atom or an organic group. The sum of the number of carbon atoms of R⁷, R⁸, and R⁹ is 1 or more.

In the case of R⁷, R⁸, or R⁹ being organic groups, the organic groups are the same as in the case of R¹, R², or R³ being organic groups.

Specific examples of the silylating agent represented by the above Formula (2) include hexamethyldisilazane, N-methyl hexamethyldisilazane, 1,1,3,3-tetramethyl disilazane, 1,3-dimethyl disilazane, 1,3-di-n-octyl-1,1,3,3-tetramethyl disilazane, 1,3-divinyl-1,1,3,3,-tetramethyl disilazane, tris(dimethyl silyl)amine, tris(trimethylsilyl)amine, 1-ethyl-1,1,3,3,3-pentamethyl disilazane, 1-vinyl-1,1,3,3,3-pentamethyl disilazane, 1-propyl-1,1,3,3,3-pentamethyl disilazane, 1-phenylethyl-1,1,3,3,3-pentamethyl disilazane, 1-tert-butyl-1,1,3,3,3-pentamethyl disilazane, 1-phenyl-1,1,3,3,3-pentamethyl disilazane and 1,1,1-trimethyl-3,3,3-triethyl disilazane.

### (Silylating Agent Represented by Formula (3))

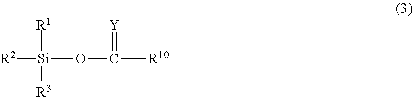

In the above Formula (3), R¹, R², and R³ are the same as in the above Formula (1). Y represents 0, CHR¹¹, CHOR¹¹, CR¹¹R¹¹, or NR¹². R¹¹ and R¹² each independently represent a hydrogen atom, a saturated or unsaturated chain hydrocarbon group, a saturated or unsaturated non-aromatic cyclic hydrocarbon group, a trialkyl silyl group, a trialkyl siloxy group, an alkoxy group, a phenyl group, a phenyl ethyl group, or an acetyl group. R¹⁰ represents a hydrogen atom, an alkyl group, or a trialkyl silyl group.

In the case of R¹¹ and R¹² being saturated or unsaturated chain hydrocarbon groups or saturated or unsaturated non-aromatic cyclic hydrocarbon groups, the saturated or unsaturated chain hydrocarbon groups or saturated or unsaturated non-aromatic cyclic hydrocarbon groups are the same as in the case of R⁵ being a saturated or unsaturated chain hydrocarbon group or a saturated or unsaturated non-aromatic cyclic hydrocarbon group in the above Formula (1).

In the case of R¹¹ and R¹² being trialkyl silyl groups, a trialkyl slioxy or alkoxy groups, the number of carbon atoms of the alkyl groups included therein is not particularly limited. The number of carbon atoms of the alkyl group included therein is preferably 1 to 10, more preferably 1 to 8, and still more preferably 1 to 3. Suitable examples of the alkyl group included therein may include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group and an n-decyl group. Among these alkyl groups, a methyl group, an ethyl group, and an n-propyl group are more preferable, and a methyl group and an ethyl group are still more preferable.

In the case of R¹⁰ being an alkyl group or a trialkyl silyl group, the number of carbon atoms of the alkyl groups included in an alkyl group or a trialkyl silyl group is not particularly limited. The carbon number of the alkyl group included in an alkyl group or a trialkyl silyl group is preferably 1 to 10, more preferably 1 to 8, and still more preferably 1 to 3. Suitable examples of the alkyl group included in an alkyl group or a trialkyl silyl group may include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group and an n-decyl group. Among these alkyl groups, a methyl group, an ethyl group, and an n-propyl group are more preferable, and a methyl group and an ethyl group are still more preferable.

Specific examples of the silylating agent represented by the above Formula (3) may include trimethylsilyl acetate, dimethylsilyl acetate, monomethylsilyl acetate, trimethylsilyl propionate, trimethylsilyl butylate and trimethylsilyl-2-butenoate.

### (Silylating Agent Represented by Formula (4))

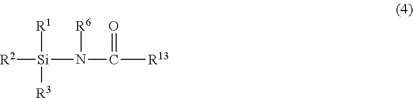

In the above Formula (4), R¹, R², and R³ are the same as in the above Formula (1). R⁶ is the same as the above Formula (2). R¹³ represents a hydrogen atom, a saturated or unsaturated chain hydrocarbon group, a trifluoromethyl group, or a trialkylsilyl amino group.

In the case of R¹³ being a saturated or unsaturated chain hydrocarbon group, the saturated or unsaturated chain hydrocarbon group is the same as the case of R⁴ being a saturated or unsaturated chain hydrocarbon group in the above Formula (1).

In the case of R¹³ being a trialkylsilyl amino group, the alkyl group included in the trialkylsilyl amino group is the same as the alkyl group included therein in the case of R¹¹ and R¹² being trialkyl silyl groups, trialkyl siloxy groups, or alkoxy groups in the above Formula (3).

Specific examples of the silylating agent represented by the above Formula (4) may include N,N′-bis(trimethylsilyl)urea, N-trimethylsilyl acetamide, N-methyl-N-trimethylsilyl trifluoro acetamide and N,N-bis(trimethylsilyl)trifluoro acetamide.

### (Silylating Agent Represented by Formula (5))

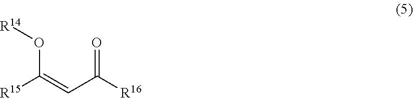

In the above Formula (5), R¹⁴ represents a trialkyl silyl group. R¹⁵ and R¹⁶ each independently represent a hydrogen atom or an organic group.

In the case of R¹⁴ being a trialkyl silyl group, the alkyl group included in the trialkyl silyl group is the same as the alkyl group included therein in the case of R¹¹ and R¹² being trialkyl silyl groups, trialkyl siloxy groups, or alkoxy groups in the above Formula (3).

In the case of R¹⁵ and R¹⁶ being organic groups, the organic groups are the same as the organic groups in the case of R¹, R², or R³ being organic groups in the above Formula (1).

Specific examples of the silylating agent represented by the above Formula (5) may include 2-trimethylsiloxypentane-2-ene-4-one.

### (Silylating Agent Represented by Formula (6))

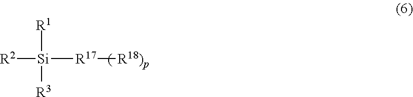

In the above Formula (6), R¹, R², and R³ are the same as in the above Formula (1). R¹⁷ represents a saturated or unsaturated chain hydrocarbon group, a saturated or unsaturated non-aromatic cyclic hydrocarbon group, or a non-aromatic heterocyclic group. R¹⁸ represents —SiR¹R²R³. p represents 0 or 1.

When p is 0, the saturated or unsaturated chain hydrocarbon group, saturated or unsaturated non-aromatic cyclic hydrocarbon group, or non-aromatic heterocyclic group as R¹⁷ is the same as R⁵ in the above Formula (1). When p is 1, the saturated or unsaturated chain hydrocarbon group, a saturated or unsaturated non-aromatic cyclic hydrocarbon group, and a non-aromatic heterocycle group is as R¹⁷ is a divalent group in which one hydrogen atom is removed from the monovalent group when p is 0.

Specific examples of the silylating agent represented by the above Formula (6) may include 1,2-bis(dimethyl chlorosilyl)ethane and tert-butyldimethyl chlorosilane.

### (Silylating Agent Represented by Formula (7))

R¹⁹_{q}Si[N(CH₃)₂]_{4-q} (7)

In the above Formula (7), each R¹⁹ independently represents a chain hydrocarbon group having 1 to 18 carbon atoms in which some or all of the hydrogen atoms may be substituted by fluorine atoms.

q is 1 or 2.

In the above Formula (7), the number of carbon atoms of R¹⁹ is preferably 2 to 18 and more preferably 8 to 18.

Examples of R¹⁹ being a chain saturated hydrocarbon group with no substitution by fluorine atoms include a methyl group, an ethyl group, an n-propyl group, an isopropyl group, a butyl group, a sec-butyl group, a tert-butyl group, an isobutyl group, an amyl group, an isoamyl group, a tert-amyl group, a hexyl group, a 2-hexyl group, a 3-hexyl group, a heptyl group, a 2-heptyl group, a 3-heptyl group, an isoheptyl group, a tert-heptyl group, an n-octyl group, an isooctyl group, a tert-octyl group, a 2-ethyl hexyl group, a nonyl group, an isononyl group, a decyl group, a dodecyl group, an tridecyl group, a tetradecyl group, a pentadecyl group, a hexadecyl group, a heptadecyl group and an octadecyl group.

Examples of R¹⁹ being a chain unsaturated hydrocarbon group with no substitution by fluorine atoms include a vinyl group, a 1-propenyl group, an allyl group, an isopropenyl group, a 1-butenyl group, a 2-butenyl group, a 3-butenyl group, a 1,3-butadienyl group, a 1-ethyl vinyl group, a 1-methyl-1-propenyl group, a 1-methyl-2-propenyl group, a 4-pentenyl group, a 1,3-pentadienyl group, a 2,4-pentadienyl group, a 3-methyl-1-butenyl group, a 5-hexenyl group, a 2,4-hexadienyl group, a 6-heptenyl group, a 7-octenyl group, an 8-nonenyl group, a 9-decenyl group, a 10-undecenyl group, a 11-dodecenyl group, a 12-tridecenyl group, a 13-tetradecenyl group, a 14-pentadecenyl group, a 15-hexadecenyl group, a 16-heptadecenyl group, a 17-octadecenyl group, an ethynyl group, a propargyl group, a 1-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 6-heptynyl group, a 7-octynyl group, a 8-nonynyl group, a 9-decynyl group, a 10-undecynyl group, a 11-dodecynyl group, a 12-tridecynyl group, a 13-tetradecynyl group, a 14-pentadecynyl group, a 15-hexadecynyl group, a 16-heptadecynyl group and a 17-octadecynyl group.

In the case of R¹⁹ being a chain hydrocarbon group with no substitution by fluorine atoms, the number and site of the substitution of the fluorine atom are not particularly limited. The number of the substitution of the fluorine atom in the chain hydrocarbon group is preferably 50% or more, more preferably 70% or more, and still more preferably 80% or more of the number of the hydrogen atoms included in the chain hydrocarbon group.

R¹⁹ is preferably a linear hydrocarbon group having 1 to 18 carbon atoms in which some or all of the hydrogen atoms may be substituted by a fluorine atom, because an excellent hydrophobization effect can easily be attained. In addition, R¹⁹ is preferably a saturated linear chain hydrocarbon group having 1 to 18 carbon atoms (an alkyl group having 1 to 18 carbon atoms), in which some or all of the hydrogen atoms may be substituted by a fluorine atom, from the viewpoint of the storage stability of the silylating agent.

In the above Formula (7), q is 1 or 2, and preferably 1.

### (Silylating Agent Represented by Formula (8))

R²⁰ᵣ[N(CH₃)₂]₃₋ᵣSi—R²²—SiR²¹ₛ[N(CH₃)₂]₃₋ₛ (8)

In the above Formula (8), R²⁰ and R²¹ each independently represent a hydrogen atom, or a linear or branched alkyl group having 1 to 4 carbon atoms. R²² represents a linear or branched alkylene group having 1 to 16 carbon atoms. r and s each independently represent integers of 0 to 2.

Specific examples of R²⁰ and R²¹ being linear or branched alkyl groups having 1 to 4 carbon atoms include a methyl group, an ethyl group, an n-propyl group, an isopropyl group, an n-butyl group, a sec-butyl group, a tert-butyl group and an isobutyl group.

R²⁰ and R²¹ are preferably a hydrogen atom, or a linear or branched alkyl group having 1 to 3 carbon atoms, more preferably a hydrogen atom or a methyl group, and still more preferably a methyl group.

The linear or branched alkylene group as R²² has preferably 1 to 10 carbon atoms, and more preferably 2 to 8 carbon atoms. In addition, the linear chain alkylene group is a methylene group or an α,ω-linear chain alkylene group, and the branched alkylene group is a methylene group and an alkylene group other than an α,ω-linear chain alkylene group. R²² is preferably the linear chain alkylene group.

Examples of R²² being a linear or branched alkylene group having 1 to 16 carbon atoms include a methylene group, a 1,2-ethylene group, a 1,1-ethylene group, a propane-1,3-diyl group, a propane-1,2-diyl group, a propane-1,1-diyl group, a propane-2,2-diyl group, a butane-1,4-diyl group, a butane-1,3-diyl group, a butane-1,2-diyl group, a butane-1,1-diyl group, a butane-2,2-diyl group, a butane-2,3-diyl group, a pentane-1,5-diyl group, a pentane-1,4-diyl group, a hexane-1,6-diyl group, a heptane-1,7-diyl group, an octane-1,8-diyl group, a 2-ethyl hexane-1,6-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group and a hexadecane-1,16-diyl group.

In the above Formula (8), s and r each independently represent integers of 0 to 2. Since the synthesis and obtaining are easy, s and r are preferably 1 or 2, and more preferably 2.

### (Cyclic Silazane Compound)

Examples of the cyclic silazane compound may include cyclic disilazane compounds such as 2,2,5,5-tetramethyl-2,5-disila-1-azacyclopentane and 2,2,6,6-tetramethyl-2,6-disila-1-azacyclohexane; cyclic trisilazane compounds such as 2,2,4,4,6,6-hexamethylcyclotrisilazane and 2,4,6-trimethyl-2,4,6-trivinylcyclotrisilazane; cyclic tetrasilazane compounds such as 2,2,4,4,6,6,8,8-octamethylcyclotetrasilazane; and the like.

Among them, the cyclic disilazane compounds are preferable, and 2,2,5,5-tetramethyl-2,5-disila-1-azacyclopentane and 2,2,6,6-tetramethyl-2,6-disila-1-azacyclohexane are more preferable. As the cyclic disilazane compounds, there are a 5-membered ring structure such as 2,2,5,5-tetramethyl-2,5-disila-1-azacyclopentane and a 6-membered ring structure such as 2,2,6,6-tetramethyl-2,6-disila-1-azacyclohexane, but the 5-membered ring structure is more preferable.

The above-described silylating agents may be used singly or in combination of two types or more thereof.

The percentage content of the silylating agent (A) included in the first surface treatment liquid is practically preferably 0.1% by mass or more, more preferably 0.1 to 30% by mass, still more preferably 0.5 to 20% by mass, and particularly preferably 1 to 15% by mass.

### [Solvent (S)]

A solvent (S) included in the first surface treatment liquid does not have a hydroxyl group bonded to a carbon atom, and satisfies the following conditions (i) and (ii). (i) A value of dH in Hansen solubility parameters of the solvent (S) is 3.2 MPa^{1/2} or less or 10.5 MPa^{1/2} or more. (ii) Relative Energy Difference represented by Rₐ/R₀ is 1.2 or more, where the interaction radius of the polyvinyl chloride in the Hansen space is defined as R₀, and a distance between the Hansen solubility parameters of the polyvinyl chloride and Hansen solubility parameters of the solvent (S) is defined as Rₐ.

When the first surface treatment liquid includes a solvent (S) together with a silylating agent (A), when surface treatment of the treatment target is carried out using a device having a liquid contact portion provided with a member made of polyvinyl chloride, hydrophobizing (silylating) of a surface of a treatment target can be highly carried out while deterioration of polyvinyl chloride is suppressed. Furthermore, since the solvent (S) does not include a hydroxyl group bonded to a carbon atom, even when silylating agents such as N,N-dimethylaminotrimethylsilane (TMSDMA) and hexamethyl disilazane (HMDS), which easily react with an alcoholic hydroxyl group are used, reaction between the solvent (S) and the silylating agent is suppressed. Thus, the surface of the treatment target can be highly hydrophobized (silylated).

Herein, the Hansen solubility parameters is a value used for predicting the solubility of substances such as a polymer and described in detail in, for example, “Hansen Solubility Parameters: A User's Handbook” by Charles M. Hansen (CRC Press, 2007) or “The CRC Handbook and Solubility Parameters and Cohesion Parameters” (1999) edited by Allan F. M. Barton.

Hansen solubility parameters includes the following three parameters (unit: MPa^{1/2}). These three parameters can be regarded as coordinates in three-dimensional space called the Hansen space.

dD: dispersion term (The energy from dispersion forces between molecules)
dP: polarization term (The energy from dipolar intermolecular force between molecules)
dH: hydrogen bond term (The energy from hydrogen bonds between molecules)

In the first surface treatment liquid, a value of dH that is the hydrogen bond term of the Hansen solubility parameters of the solvent (S) is 3.2 MPa^{1/2} or less or 10.5 MPa^{1/2} or more. When the value of dH is 3.2 MPa^{1/2} or less, the lower limit value is not particularly limited, and it may be 0.0 MPa^{1/2}. Furthermore, when the value of dH is 10.5 MPa^{1/2} or more, the upper limit value is not particularly limited and may be, for example, 27.2 MPa^{1/2}.

Furthermore, in the first surface treatment liquid, Relative Energy Difference represented by Rₐ/R₀ is 1.2 or more, wherein the interaction radius of the polyvinyl chloride in the Hansen space is defined as R₀, and a distance between the Hansen solubility parameters of the polyvinyl chloride and Hansen solubility parameters of the solvent (S) is defined as Rₐ. The upper limit value of Rₐ/R₀ is not particularly limited, and may be, for example, 3.0.

The interaction radius R₀ of polyvinyl chloride represents a distance from the center coordinate in which the solubility of polyvinyl chloride is exhibited where the center coordinate is coordinate of Hansen solubility parameters of polyvinyl chloride. The interaction radius R₀ of polyvinyl chloride is usually determined by carrying out a solubility test of dissolving polyvinyl chloride in various solvents whose Hansen solubility parameters have been determined. Specifically, when all the coordinates of Hansen solubility parameters used in the solubility test are plotted in the Hansen space, coordinates of solvents that dissolve polyvinyl chloride are inside a sphere, and coordinates of solvents that do not dissolve polyvinyl chloride are outside the sphere, and such a sphere (solubility sphere) is found out. Then, the radius of the solubility sphere is defined as the interaction radius R₀ of polyvinyl chloride.

Furthermore, the distance Rₐ between the Hansen solubility parameters of the polyvinyl chloride and Hansen solubility parameters of the solvent (S) can be determined by the following Formula (I). In the Formula (I), dD₁, dP₁, and dH₁ represents the dispersion term, the polarization term, and the hydrogen bond term of Hansen solubility parameters of polyvinyl chloride, respectively. Furthermore, dD₂, dP₂, and dH₂ represents the dispersion term, the polarization term, and the hydrogen bond term of Hansen solubility parameters of solvent (S), respectively.

(Rₐ)²=4(dD₁−dD₂)²+(dP₁−dP₂)²+(dH₁−dH₂)² (I)

As dD, dP, and dH of Hansen solubility parameters of polyvinyl chloride, for example, 15.2 MPa^{1/2}, 6.7 MPa^{1/2}, and 5.3 MPa^{1/2} can be employed, respectively. Furthermore, as the interaction radius R₀ of the polyvinyl chloride, for example, 4.2 MPa^{1/2} can be employed.

The solvent (S) may be a single solvent or may be a combination of two or more solvents as long as it satisfies the above-mentioned conditions (i) and (ii). When the solvent (S) is made of two or more solvents, the Hansen solubility parameters of the solvent (S) can be determined by the weighted mean of the Hansen solubility parameters of the respective solvents. Note here that the Hansen solubility parameters of the respective solvents can be predicted using computer software (Hansen Solubility Parameters in Practice (HSPiP)).

From the viewpoint of satisfying the above-mentioned conditions (i) and (ii), the solvent (S) preferably includes one or more selected from aliphatic hydrocarbon, an alkoxysilane compound represented by the following Formula (S1):

SiR^{s1}₍₄₋ₐ₎R^{s2}ₐ (S1)

(in the Formula (S1), R^{s1} represents an alkoxy group having 1 to 4 carbon atoms, R^{s1} represents an alkyl group having 1 to 4 carbon atoms, and a is an integer of 0 to 3), and dialkyl ether (hereinafter, also referred to as a “specific solvent”).

Examples of the aliphatic hydrocarbon include aliphatic hydrocarbon having 5 to 20 carbon atoms, such as n-hexane, n-heptane, n-octane, n-nonane, methyloctane, n-decane, n-undecane, n-dodecane, 2,2,4,6,6-pentamethyl heptane, 2,2,4,4,6,8,8-heptamethyl nonane, cyclohexane, methyl cyclohexane, and bicyclohexyl.

Examples of the alkoxysilane compound represented by the above Formula (S1) include tetraalkoxysilane such as tetramethoxysilane, tetraethoxysilane, tetra-n-propoxysilane, and tetra-n-butoxysilane; trialkoxysilane such as trimethoxysilane, triethoxysilane, and tri-n-propoxysilane; monoalkyl trialkoxysilane such as methyltrimethoxysilane, methyltriethoxysilane, methyl tri-n-propoxysilane, methyl tri-n-butoxysilane, ethyltrimethoxysilane, ethyltriethoxysilane, ethyltri-n-propoxysilane, ethyltri-n-butoxysilane, n-propyl trimethoxysilane, n-propyl triethoxysilane, n-butyl trimethoxysilane, and n-butyl triethoxysilane; dialkoxysilane such as dimethoxysilane, diethoxysilane, and di-n-propoxysilane; monoalkyl dialkoxysilane such as methyl dimethoxysilane, methyl diethoxysilane, methyl di-n-propoxysilane, ethyldimethoxysilane, ethyldiethoxysilane, ethyldi-n-propoxysilane, n-propyl dimethoxysilane, n-propyl diethoxysilane, and n-propyl di-n-propoxysilane; dialkoxy dialkyl silane such as dimethyl dimethoxysilane, dimethyl diethoxysilane, dimethyl di-n-propoxysilane, diethyl dimethoxysilane, diethyl diethoxysilane, diethyl di-n-propoxysilane, di-n-propyl dimethoxysilane, di-n-propyl diethoxysilane, di-n-propyl di-n-propoxysilane, and di-n-butyl dimethoxysilane; trialkyl monoalkoxysilane such as trimethylmethoxysilane and tri-n-butylethoxysilane; and the like.

Examples of the dialkyl ether include dialkyl ethers having 2 to 12 carbon atoms, including dimethyl ether, diethyl ether, methylethyl ether, di-n-propyl ether, diisopropyl ether, di-n-butyl ether, diisoamyl ether, and di-n-hexyl ether.

Among these specific solvents, at least one selected from the group consisting of n-decane, tetraethoxysilane, dimethyl diethoxysilane, methyltriethoxysilane, diisoamyl ether, and di-n-hexyl ether is preferable, and at least one selected from the group consisting of tetraethoxysilane and dimethyl diethoxysilane is more preferable.

The percentage content of the specific solvent contained in the solvent (S) is preferably 30% by volume or more, more preferably 50% by volume or more, and still more preferably 75% by volume or more with respect to the total mass of the solvent (S).

The solvent (S) may include the other solvents other than the above-mentioned specific solvents as long as it satisfies the above-mentioned conditions (i) and (ii). Examples of the other solvents include: sulfoxides such as dimethylsulfoxide; sulfones such as dimethylsulfone, diethylsulfone, bis(2-hydroxyethyl)sulfone, and tetramethylene sulfone; amides such as N,N-dimethylformamide, N-methylformamide, N,N-dimethylacetamide, N-methylacetamide, and N,N-dimethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; other ethers such as dimethyl glycol, dimethyl diglycol, dimethyl trigylcol, methylethyl diglycol, diethyl glycol, diethylene glycol dimethyl ether, diethylene glycol methylethyl ether, diethylene glycol diethyl ether, triethylene glycol dimethyl ether, and tetraethylene glycol dimethyl ether; (poly)alkylene glycol monoalkyl ether acetates such as ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate, and propylene glycol monoethyl ether acetate; other esters such as methyl 2-hydroxypropionate, ethyl 2-hydroxypropionate, 2-hydroxy-2-methylpropionic acid ethyl, 3-methoxypropionic acid methyl, 3-methoxypropionic acid ethyl, 3-ethoxypropionic acid methyl, 3-ethoxypropionic acid ethyl, ethoxyacetic acid ethyl, hydroxyacetic acid ethyl, 2-hydroxy-3-methylbutanoic acid methyl, 3-methoxy butyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate; ketones such as methylethyl ketone, cyclohexanone, 2-heptanone, and 3-heptanone; lactones such as β-propiolactone, γ-butyrolactone, and δ-pentyrolactone; aromatic hydrocarbons such as benzene, toluene, xylene, 1,3,5-trimethyl benzene, and naphthalene; terpenes such as p-menthane, diphenyl menthane, limonene, terpinene, bornane, norbornane and pinane; and the like.

The percentage content of the solvent (S) included in the first surface treatment liquid is preferably 50 to 99.9% by mass, more preferably 80 to 99% by mass, and still more preferably 85 to 98% by mass.

[Nitrogen-Containing Heterocyclic Compound (B)]

The first surface treatment liquid may further include a nitrogen-containing heterocyclic compound (B) that does not include a silicon atom (hereinafter, also simply referred to as a “nitrogen-containing heterocyclic compound (B)”). When the first surface treatment liquid further includes a nitrogen-containing heterocyclic compound (B), the silylation reaction by a silylating agent (A) is promoted by the catalytic action by the nitrogen-containing heterocyclic compound (B). As a result, when the surface treatment is carried out for the time as in the case where the nitrogen-containing heterocyclic compound (B) is not included, the surface of the treatment target can be more highly hydrophobized. When the hydrophobization is carried out at the same level as in the case where the nitrogen-containing heterocyclic compound (B) is not included, the surface treatment time for the treatment target can be shortened.

The nitrogen-containing heterocyclic compound (B) is not particularly limited as long as it is a compound which does not include a silicon atom and which includes a nitrogen atom in the ring structure thereof. The heterocyclic compound may include, for example, an oxygen atom and a sulfur atom, that is, a hetero atom other than a nitrogen atom, in the ring structure thereof. It is preferable that the nitrogen-containing heterocyclic compound (B) is a compound including nitrogen-containing heterocycle having aromatic property. When the nitrogen-containing heterocyclic compound (B) includes a nitrogen-containing heterocycle having an aromatic property, it is possible to increase the hydrophobicity of the surface of the treatment target that has been treated with a surface treatment agent.

The nitrogen-containing heterocyclic compound (B) may be a compound in which two or more rings are bonded by a single bond, or a compound bonded by bi- or poly-valent linking group. In this case, two or more rings bonded by a linking group are only required to include at least one nitrogen-containing heterocycle. In the poly-valent linking group, divalent linking groups are preferable from the viewpoint that the steric hindrance between rings is small. Specific examples of the divalent linking group include an alkylene group having 1 to 6 carbon atoms, —CO—, —CS—, —O—, —S—, —NH—, —N═N—, —CO—O—, —CO—NH—, —CO—S—, —CS—O—, —CS—S—, —CO—NH—CO—, —NH—CO—NH—, —SO—, —SO₂—, and the like. The number of rings included in the compound in which two or more rings are bonded by the poly-valent linking group is preferably 4 or less, more preferably 3 or less, and still more preferably 2 from the viewpoint of easiness in preparing a uniform surface treatment liquid. Note here that, for example, in a condensed ring such as a naphthalene ring, the number of rings is 2.

The nitrogen-containing heterocyclic compound (B) may be a nitrogen-containing heterocyclic compound in which a plurality of rings are condensed. In this case, at least one ring among the rings constituting the condensed ring is only required to be a nitrogen-containing heterocycle. The number of rings included in the nitrogen-containing heterocyclic compound (B) in which a plurality of rings are condensed is preferably 4 or less, preferably 3 or less, and the more preferably 2 from the viewpoint of easiness in preparing a uniform surface treatment liquid.

From the viewpoint that an effect of the surface treatment using the first surface treatment liquid is excellent, the nitrogen-containing heterocyclic compound (B) preferably includes a condensed polycyclic including a nitrogen-containing five-membered ring or a nitrogen-containing five-membered ring skeleton.

Suitable examples of the nitrogen-containing heterocyclic compound include pyridine, pyridazine, pyrazine, pyrimidine, triazine, tetrazine, pyrrole, pyrazole, imidazole, triazole, tetrazole, oxazole, isoxazole, triazole, isothiazole, oxadiazole, thiadiazole, quinoline, isoquinoline, cinnoline, phthalazine, quinoxaline, quinazoline, indole, indazole, benzimidazole, benzotriazole, benzoxazole, benzisoxazole, benzothiazole, benzoisothiazole, benzoxadiazole, benzothiadiazole, saccharin, pyrrolidine, and, piperidine. Among these, pyrrole, pyrazole, imidazole, triazole, tetrazole, oxazole, isoxazole, triazole, isothiazole, oxadiazole, thiadiazole, indole, indazole, benzimidazole, benzotriazole, benzoxazole, benzoisoxazole, benzothiazole, benzoisothiazole, benzoxadiazole, benzothiadiazole, and saccharin are preferable, and imidazole, triazole, tetrazole, benzotriazole, and pyrazole are more preferable. The nitrogen-containing heterocyclic compound having a substituent is also preferably used.

Examples of the substituents which the nitrogen-containing heterocyclic compound may have include an alkyl group having 1 to 6 carbon atoms, a cycloalkyl group having 3 to 8 carbon atoms, an alkoxy group having 1 to 6 carbon atoms, a cycloalkyloxy group having 3 to 8 carbon atoms, an aryl group having 6 to 20 carbon atoms, an aralkyl group having 7 to 20 carbon atoms, an alkyl halide group having 1 to 6 carbon atoms, an aliphatic acyl group having 2 to 7 carbon atoms, an aliphatic acyl halide group having 2 to 7 carbon atoms, an aryl carbonyl group having 7 to 20 carbon atoms, a carboxyalkyl group having 2 to 7 carbon atoms, a halogen atom, a hydroxyl group, a mercapto group, an alkylthio group having 1 to 6 carbon atoms, an amino group, a monoalkyl amino group including an alkyl group having 1 to 6 carbon atoms, a dialkyl amino group including an alkyl group having 1 to 6 carbon atoms, a nitro group, a cyano group, and the like. The nitrogen-containing heterocyclic compound may have a plurality of substituents on the nitrogen-containing heterocycle thereof. When a plurality of substituents are included, the plurality of substituents may be the same as or different from each other. When these substituents include an aliphatic hydrocarbon ring, an aromatic hydrocarbon ring, or the like, these rings may further include the same substituents as the substituents which the nitrogen-containing heterocyclic compound may have.

The number of carbon atoms of the alkyl group as a substituent is 1 to 6, preferably 1 to 4, and more preferably 1 or 2. Specific examples of the alkyl group having 1 to 6 carbon atoms include a methyl group, an ethyl group, an n-propyl group, an isopropyl group, an n-butyl group, an isobutyl group, a sec-butyl group, a tert-butyl group, an n-pentyl group, an n-hexyl group, and the like. Among these, a methyl group and an ethyl group are preferable, and a methyl group is more preferable.

The number of carbon atoms of the cycloalkyl group as a substituent is 3 to 8, preferably 3 to 7, and more preferably 4 to 6. Specific examples of the cycloalkyl group having 3 to 8 carbon atoms include a cyclopropyl group, a cyclobutyl group, a cyclopentyl group, a cyclohexyl group, and a cycloheptyl group, and a cyclooctyl group.

The number of carbon atoms of the alkoxy group as a substituent is 1 to 6, preferably 1 to 4, and more preferably 1 or 2. Specific examples of the alkoxy group having 1 to 6 carbon atoms include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an n-hexyloxy group, and the like. Among these, a methoxy group and an ethoxy group are preferable, and a methoxy group is more preferable.

The number of carbon atoms of the cycloalkyloxy group as a substituent is 3 to 8, preferably 3 to 7, and more preferably 4 to 6. Specific examples of the cycloalkyloxy group having 3 to 8 carbon atoms include a cyclopropyloxy group, cyclobutyloxy group, a cyclopentyloxy group, a cyclohexyloxy group, a cycloheptyloxy group, and a cyclo-octyloxy group.

The number of carbon atoms of the aryl group as a substituent is 6 to 20, and preferably 6 to 12. Specific examples of the aryl group having 6 to 20 carbon atoms include a phenyl group, α-naphthyl group, a β-naphthyl group, biphenyl-4-yl group, a biphenyl-3-yl group, a biphenyl-2-yl group, an anthracene-1-yl group, an anthracene-2-yl group, an anthracene-9-yl group, a phenanthrene-1-yl group, a phenanthrene-2-yl group, a phenanthrene-3-yl group, a phenanthrene-4-yl group, and a phenanthrene-9-yl group. Among these, a phenyl group, an α-naphthyl group, a β-naphthyl group, a biphenyl-4-yl group, a biphenyl-3-yl group, and a biphenyl-2-yl group are preferable, and a phenyl group is more preferable.

The number of carbon atoms of the aralkyl group as a substituent is 7 to 20, and preferably 7 to 12. Specific examples of the aralkyl group having 7 to 20 carbon atoms include a benzyl group, a phenethyl group, a 3-phenyl-n-propyl group, a 4-phenyl-n-butyl group, an α-naphthyl methyl group, a β-naphthyl methyl group, a 2-(α-naphthyl)ethyl group, and a 2-(β-naphthyl)ethyl group. Among these groups, a benzyl group and a phenethyl group are preferable, and a benzyl group is more preferable.

Examples of the halogen atom included in an alkyl halide group as a substituent include a fluorine atom, a chlorine atom, a bromine atom, and an iodine atom. The number of carbon atoms of the alkyl halide group as a substituent is 1 to 6, preferably 1 to 4, and more preferably 1 or 2. Specific examples of the alkyl halide group having 1 to 6 carbon atoms include a chloromethyl group, a dichioromethyl group, a trichioromethyl group, a fluoromethyl group, a difluoromethyl group, a trifluoromethyl group, a 1,1-difluoroethyl group, a 2,2,2-trifluoroethyl group, and a pentafluoroethyl group.

The number of carbon atoms of the aliphatic acyl group as a substituent is 2 to 7, preferably 2 to 5, and more preferably 2 or 3. Specific examples of the aliphatic acyl group having 2 to 7 carbon atoms include an acetyl group, a propionyl group, a butanoyl group, a pentanoyl group, a hexanoyl group, and a heptanoyl group. Among these, an acetyl group and a propionyl group are preferable, and an acetyl group is more preferable.

Examples of the halogen atom included in the aliphatic acyl halide group as a substituent include a fluorine atom, a chlorine atom, a bromine atom, and an iodine atom. The number of carbon atoms of the aliphatic acyl halide group as a substituent is 2 to 7, preferably 2 to 5, and more preferably 1 or 2. Specific examples of the aliphatic acyl halide group having 2 to 7 carbon atoms include a chloroacetyl group, a dichloroacetyl group, a trichloroacetyl group, a fluoroacetyl group, a difluoroacetyl group, a trifluoroacetyl group, and a pentafluoropropionyl group.

The number of carbon atoms of the aryl carbonyl group as a substituent is 7 to 20, and preferably 7 to 13. Specific examples of the aryl carbonyl group having 7 to 20 carbon atoms include a benzoyl group, an α-naphthoyl group, and a β-naphthoyl group.

The number of carbon atoms of the carboxyalkyl group as a substituent is 2 to 7, preferably 2 to 5, and more preferably 2 or 3. Specific examples of the carboxyalkyl group having 2 to 7 carbon atoms include a carboxymethyl group, a 2-carboxyethyl group, a 3-carboxy-n-propyl group, a 4-carboxy-n-butyl group, a 5-carboxy-n-pentyl group, and a 6-carboxy-n-hexyl group. Among these, a carboxymethyl group is preferable.

Examples of the halogen atom include a fluorine atom, a chlorine atom, a bromine atom, and an iodine atom. Among these, a fluorine atom, a chlorine atom, and a bromine atom are preferable, and a chlorine atom and a bromine atom are more preferable.

The number of carbon atoms of the alkylthio group as a substituent is 1 to 6, preferably 1 to 4, and more preferably 1 or 2. Specific examples of the alkylthio group having 1 to 6 carbon atoms include a methylthio group, an ethylthio group, an n-propylthio group, an isopropylthio group, an n-butylthio group, an isobutylthio group, a sec-butylthio group, a tert-butylthio group, an n-pentylthio group, an n-hexylthio group, and the like. Among these, a methylthio group and an ethylthio group are preferable, and a methylthio group is more preferable.

Specific examples of alkyl groups included in the monoalkyl amino group including an alkyl group having 1 to 6 carbon atoms, and in the dialkyl amino group including the alkyl group having 1 to 6 carbon atoms are similar to the above-mentioned specific examples of the alkyl group as the substituent. As the monoalkyl amino group including an alkyl group having 1 to 6 carbon atoms, an ethyl amino group and a methyl amino group are preferable, and a methyl amino group is more preferable. As the dialkyl amino group including an alkyl group having 1 to 6 carbon atoms, a diethyl amino group and a dimethyl amino group are preferable, and a dimethyl amino group is more preferable.

Particularly suitable examples of the nitrogen-containing heterocyclic compound (B) include a compound represented by the following Formula.

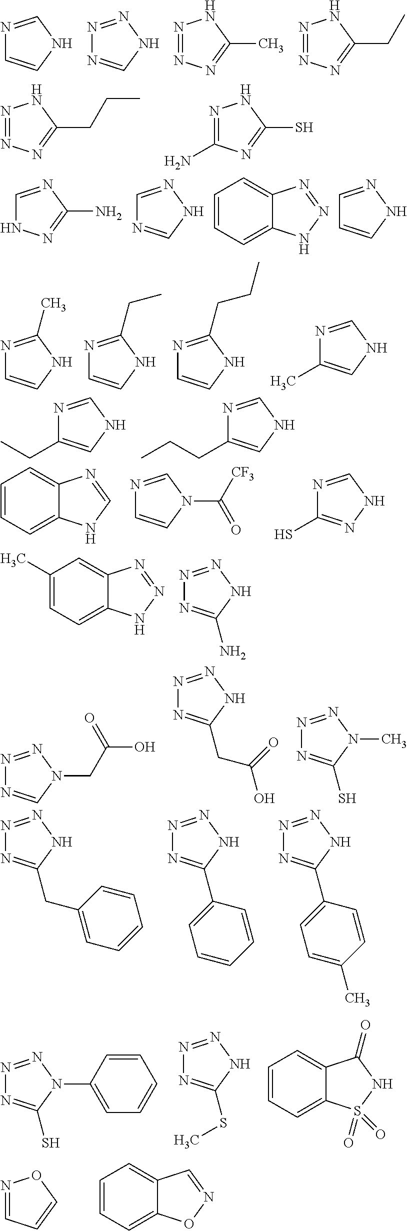

When the first surface treatment liquid includes the nitrogen-containing heterocyclic compound (B), the percentage content of the nitrogen-containing heterocyclic compound (B) is preferably 0.001 to 20% by mass, more preferably 0.01 to 10% by mass, still more preferably 0.03 to 5% by mass, and particularly preferably 0.05 to 3% by mass.

<Second Surface Treatment Liquid>

A second surface treatment liquid according to the exemplary embodiment is a surface treatment liquid to be used for surface treatment of a treatment target, includes a silylating agent (A), and a solvent (S). The silylating agent (A) does not have an alkoxy group bonded to a silicon atom, and the solvent (S) does not have a hydroxyl group bonded to a carbon atom, and includes an alkoxysilane compound represented by the following Formula (S1):

SiR^{s1}₍₄₋ₐ₎R^{s2}ₐ (S1)

(in the Formula (S1), R^{s1} represents an alkoxy group having 1 to 4 carbon atoms, R^{s2} represents an alkyl group having 1 to 4 carbon atoms, and a represents an integer of 0 to 3).

Examples of the treatment target that is the target of silylation treatment include a substrate to be used for manufacturing semiconductor devices. Surfaces of the treatment target include a surface of the substrate itself, as well as surfaces of an inorganic pattern and a resin pattern provided on a substrate, as well as surfaces of an inorganic layer and an organic layer that have not been patterned. The inorganic pattern and a resin pattern provided on a substrate, as well as the surfaces of an inorganic layer and an organic layer that have not been patterned are as already mentioned, and therefore the descriptions are omitted herein.

Examples of the silylating agent (A) included in the second surface treatment liquid include silylating agents the same as for the first surface treatment liquid, and the percentage content thereof may be the same as that of the first surface treatment liquid.

The solvent (S) included in the second surface treatment liquid does not have a hydroxyl group bonded to a carbon atom. Thus, even when a silylating agent that is likely to be reacted with alcoholic hydroxyl groups such as N,N-dimethylaminotrimethylsilane (TMSDMA) and hexamethyl disilazane (HMDS), the reaction between the solvent (S) and the silylating agent can be suppressed, and the hydrophobization (silylation) of the substrate of the surface of the treatment target can be enhanced.

Furthermore, the solvent (S) includes an alkoxysilane compound represented by the above Formula (S1). The alkoxysilane compound represented by the above Formula (S1) is a solvent that is not easily dissolve polyvinyl chloride. Therefore, the second surface treatment liquid including alkoxysilane compound represented by the above Formula (S1) as a solvent can be suitably used when surface treatment of the treatment target is carried out using a device having a liquid contact portion provided with a member made of polyvinyl chloride. Note here that the device having a liquid contact portion provided with a member made of polyvinyl chloride is as already mentioned, and therefore the description thereof is omitted herein.

Examples of the alkoxysilane compound represented by the above Formula (S1) include tetraalkoxysilane such as tetramethoxysilane, tetraethoxysilane, tetra-n-propoxysilane, and tetra-n-butoxysilane; trialkoxysilane such as trimethoxysilane, triethoxysilane, and tri-n-propoxysilane; monoalkyl trialkoxysilane such as methyltrimethoxysilane, methyltriethoxysilane, methyl tri-n-propoxysilane, methyl tri-n-butoxysilane, ethyltrimethoxysilane, ethyltriethoxysilane, ethyltri-n-propoxysilane, ethyltri-n-butoxysilane, n-propyl trimethoxysilane, n-propyl triethoxysilane, n-butyl trimethoxysilane, and n-butyl triethoxysilane; dialkoxysilane such as dimethoxysilane, diethoxysilane, and di-n-propoxysilane; monoalkyl dialkoxysilane such as methyl dimethoxysilane, methyl diethoxysilane, methyl di-n-propoxysilane, ethyldimethoxysilane, ethyldiethoxysilane, ethyldi-n-propoxysilane, n-propyl dimethoxysilane, n-propyl diethoxysilane, and n-propyl di-n-propoxysilane; dialkoxy dialkyl silane such as dimethyl dimethoxysilane, dimethyl diethoxysilane, dimethyl di-n-propoxysilane, diethyl dimethoxysilane, diethyl diethoxysilane, diethyl di-n-propoxysilane, di-n-propyl dimethoxysilane, di-n-propyl diethoxysilane, di-n-propyl di-n-propoxysilane, and di-n-butyl dimethoxysilane; trialkyl monoalkoxysilane such as trimethylmethoxysilane and tri-n-butylethoxysilane; and the like. Among them, at least one selected from the group consisting of tetraethoxysilane, dimethyl diethoxysilane, and methyltriethoxysilane is preferable, and at least one selected from the group consisting of tetraethoxysilane and dimethyl diethoxysilane is more preferable.

The percentage content of the alkoxysilane compound represented by the above Formula (S1) included in the solvent (S) is preferably 30% by volume or more, more preferably 50% by volume or more, and still more preferably 75% by volume or more with respect to the total mass of the solvent (S).

The solvent (S) may further include at least one of aliphatic hydrocarbon and dialkyl ether in the alkoxysilane compound represented by the above Formula (S1). Examples of the aliphatic hydrocarbon and dialkyl ether include the same aliphatic hydrocarbon and dialkyl ether as those of the first surface treatment liquid.

When the solvent (S) includes at least one of aliphatic hydrocarbon and dialkyl ether, the percentage content of the total amount of the alkoxysilane compound represented by the above Formula (S1), and aliphatic hydrocarbon and dialkyl ether is preferably 30% by volume or more, more preferably 50% by volume or more, and still more preferably 75% by volume or more with respect to the total mass of the solvent (S).

Furthermore, the solvent (S) may further solvents other than the alkoxysilane compound represented by the above Formula (S1), aliphatic hydrocarbon and dialkyl ether.

The percentage content of the solvent (S) included in the second surface treatment liquid is preferably 50 to 99.9% by mass, more preferably 80 to 99% by mass, and still more preferably 85 to 98% by mass.

The second surface treatment liquid may further contain a nitrogen-containing heterocyclic compound (B) that does not include a silicon atom (hereinafter, also simply referred to as a “nitrogen-containing heterocyclic compound (B)”). Examples of the nitrogen-containing heterocyclic compound (B) which may be included by the second surface treatment liquid include the nitrogen-containing heterocyclic compound (B) that is the same as for the first surface treatment liquid, and the percentage content thereof may be the same as that of the first surface treatment liquid.

### <Surface Treatment Method>

A surface treatment method according to the exemplary embodiment is a method for carrying out surface treatment of a treatment target using a device having a liquid contact portion provided with a member made of polyvinyl chloride. The method includes bringing the above-mentioned first surface treatment liquid into contact with a surface of the treatment target.

Such a surface treatment method permits highly hydrophobizing (silylating) a surface of a treatment target while deterioration of polyvinyl chloride is suppressed when surface treatment of the treatment target such as an inorganic pattern and a resin pattern is carried out using a device having a liquid contact portion provided with a member made of polyvinyl chloride. Note here that the device having a liquid contact portion provided with a member made of polyvinyl chloride device, the treatment target, and the first surface treatment liquid are as already mentioned, and therefore the descriptions are omitted herein.

The surface treatment method according to the exemplary embodiment carries out hydrophobizing (silylating) a surface of a treatment target. The purpose of the surface treatment is not particularly limited. Representative examples of the purpose of the surface treatment include: (1) to hydrophobize a surface of a substrate that is a treatment target so as to improve the adhesion between a resin pattern composed of photoresist and substrate, and (2) to hydrophobize a surface of an inorganic pattern or a resin pattern as a treatment target, and to prevent pattern collapse during washing.

Examples of the method for providing the surface of the treatment target with the above-mentioned first surface treatment liquid include a spray method, a spin coating method, a dipping method, or the like. The surface treatment time is not particularly limited, and the surface treatment time is preferably 1 to 60 seconds. After the surface treatment, the contact angle of water on the surface of the treatment target preferably becomes 40 to 120 degrees, and more preferably becomes 60 to 100 degrees.

### EXAMPLES

Hereinafter, the present invention will be described more specifically by way of Examples, but the present invention is not limited to the following Examples.

### Examples 1 to 22 and Comparative Examples 1 to 15

### <Preparation of Surface Treatment Liquid>

Each silylating agent, nitrogen-containing heterocyclic compound, and solvent shown in Table 1 and Table 2 were mixed with each other so as to have each percentage content (% by mass) shown in the Tables to obtain surface treatment liquids of Examples and Comparative Examples. The “-” in the column of nitrogen-containing heterocyclic compounds means that a nitrogen-containing heterocyclic compound is not included. The numerical values in the column of types of solvents show the rate of each solvent (% by volume).

Abbreviations of components used in Examples and Comparative Examples are as follows.

### (Silylating Agent)

HMDS: hexamethyl disilazane

### TMSDMA: N,N-dimethylaminotrimethylsilane

### (Nitrogen-Containing Heterocyclic Compound)

BTA: benzotriazole

### (Solvent)

PGMEA: propylene glycol monomethyl ether acetate
DEDMS: diethoxy dimethyl silane
TEOS: tetraethoxysilane
MTES: methyltriethoxysilane
DIAE: diisoamyl ether
CHAX: cyclohexanol acetate
MIBC: methyl isobutyl carbinol

Hansen solubility parameters (dD, dP, and dH) of solvents used in the surface treating agents of Examples and Comparative Examples are shown in Table 1 and Table 2. Relative Energy Difference represented by Rₐ/R₀ where the interaction radius of the polyvinyl chloride in the Hansen space is defined as R₀, and a distance between the Hansen solubility parameters of the polyvinyl chloride and the Hansen solubility parameters of the solvent is defined as Rₐ is shown in Table 1 and Table 2. As the values of dD, dP, and dH of Hansen solubility parameters of polyvinyl chloride, for example, 15.2 MPa^{1/2}, 6.7 MPa^{1/2}, and 5.3 MPa^{1/2} were employed, respectively. Furthermore, as the interaction radius (R₀) of the polyvinyl chloride, for example, 4.2 MPa^{1/2} was employed.

Note here that the Hansen solubility parameters and Relative Energy Difference (RED) of solvent were predicted using computer software (Hansen Solubility Parameters in Practice (HSPiP)).

### <Evaluation of Reactivity Between Silylating Agent and Solvent>

Presence of a reaction product of a silylating agent and a solvent with respect to each surface treating agent of Examples and Comparative Examples was verified by gas chromatography-mass spectrometry (GC-MS). For a measurement device, 7890B GC System/5977A MSD manufactured by Agileit Technologies was used. Then, a case where a reaction product was not observed was evaluated as “O”, and a case where a reaction product was observed was evaluated as “X”. Results are shown in Table 1 and Table 2.

<Evaluation of Resistance of Polyvinyl Chloride with Respect to Surface Treatment Liquid>

Into a 100-mL bottle made of fluorocarbon resin (PFA), 50 mL each of surface treating agents shown in Examples and Comparative Examples were added. A member made of polyvinyl chloride (PVC) was dipped therein. Two weeks after, the weight of member was measured. Members having a change in weight after two weeks of less than 1% was evaluated as “O” and members having a change of 1% or more were evaluated as “X”. Results are shown in Table 1 and Table 2.

### <Evaluation of Hydrophobization Effect (Silylation Effect) by Surface Treatment Liquid>

Firstly, each of a silicon substrate (Si), a silicon nitride substrate (SiN), and a thermal oxidation silicon film substrate (ThOx) was dipped in a hydrofluoric acid aqueous solution having a concentration of 1% by mass at 25° C. for one minute. After dipping, the substrate was washed with ion-exchanged distilled water for one minute. The substrate after washing with water was dipped in a solution obtained by mixing 31% by mass H₂0₂ and 28% by mass NH₄OH and ion exchange distilled water in a volume ratio of 1:1:5, washed with ion exchange distilled water for one minute, and was dried by nitrogen flow.

Then, the dried substrate was dipped in the surface treatment agent of each Example and Comparative Example at 25° C. for 60 seconds to carry out the surface treatment of the substrate. The substrate after surface treatment was washed with isopropyl alcohol for one minute, and then washed with ion-exchanged distilled water for one minute. The washed substrate was dried by nitrogen flow.

Then, using Dropmaster700 (manufactured by Kyowa Interface Science Co., Ltd.), a droplet of pure water (1.8 μL) was dropped on the surface of a substrate after surface treatment, and the contact angle was measured 10 seconds after dropping. Measurement results of the contact angle are shown in Table 1 and Table 2. The “-” in the column of the contact angle means that a contact angle was not measured. Note here that when contact angle of each substrate before surface treatment was measured in the same manner, the contact angles were less than 10.0 degrees in any cases.

TABLE 1

| | | | nitrogen- | | | | | | | | | | | | |
|---|---|---|---|---|---|---|---|---|---|---|---|---|---|---|---|
| | | | containing | | | | | | | | contact angle | | | | reactivity |
| | silylating | | heterocyclic | | | | Hansen | | | | of water after | | | resistance | between |
| | agent | | compound | | solvent | | solubility | | | | surface | | | of | silylating |
| | | % by | | % by | | % by | parameters | | | | treatment (°) | | | polyvinyl | agent and |
| | type | mass | type | mass | type | mass | dD | dP | dH | RED | Si | SiN | ThOx | chloride | solvent |
| Example 1 | HMDS | 3 | BTA | 0.5 | di-n-hexyl | 96.5 | 16.0 | 3.0 | 2.9 | 1.2 | 89.2 | 59.7 | 87.4 | ◯ | ◯ |
| | | | | | ether/PGMEA = | | | | | | | | | | |
| | | | | | 99/1 | | | | | | | | | | |
| Example 2 | HMDS | 3 | BTA | 1 | DEDMS/di-n-hexyl | 96 | 14.4 | 4.0 | 1.1 | 1.3 | 88.9 | 61.2 | 89.0 | ◯ | ◯ |
| | | | | | ether = 77/23 | | | | | | | | | | |
| Example 3 | HMDS | 3 | BTA | 1 | DEDMS/ | 96 | 14.4 | 4.0 | 1.1 | 1.3 | 89.3 | 61.3 | 89.3 | ◯ | ◯ |
| | | | | | bicyclohexyl = | | | | | | | | | | |
| | | | | | 77/23 | | | | | | | | | | |
| Comparative | HMDS | 3 | BTA | 0.5 | PGMEA | 96.5 | 15.6 | 5.6 | 9.8 | 1.1 | 86.5 | 62 | 86.2 | X | ◯ |
| Example 1 | | | | | | | | | | | | | | | |
| Example 4 | HMDS | 4 | BTA | 0.5 | TEOS | 95.5 | 13.9 | 4.3 | 0.6 | 1.5 | 87.4 | 60.3 | 88.2 | ◯ | ◯ |
| Example 5 | HMDS | 4 | BTA | 0.5 | MTES | 95.5 | 14.2 | 2.8 | 2.8 | 1.2 | 88.2 | 63.0 | 86.2 | ◯ | ◯ |
| Example 6 | HMDS | 4 | BTA | 1 | TEOS/PGMEA = | 95 | 14.1 | 4.4 | 1.6 | 1.2 | 89.3 | 61.5 | 89.3 | ◯ | ◯ |
| | | | | | 89/11 | | | | | | | | | | |
| Example 7 | HMDS | 4 | — | — | n-decane | 96 | 15.7 | 0.0 | 0.0 | 2.0 | 48.1 | — | — | ◯ | ◯ |
| Example 8 | HMDS | 4 | — | — | TEOS | 96 | 13.9 | 4.3 | 0.6 | 1.5 | 54.0 | — | — | ◯ | ◯ |
| Example 9 | HMDS | 4 | — | — | TEOS/PGMEA = | 96 | 14.1 | 4.4 | 1.6 | 1.2 | 42.8 | — | — | ◯ | ◯ |
| | | | | | 89/11 | | | | | | | | | | |
| Example 10 | HMDS | 4 | — | — | DEDMS | 96 | 14.0 | 2.6 | 2.7 | 1.3 | 48.0 | — | — | ◯ | ◯ |
| Example 11 | HMDS | 4 | — | — | MTES | 96 | 14.2 | 2.8 | 2.8 | 1.2 | 44.0 | — | — | ◯ | ◯ |
| Example 12 | TMSDMA | 4 | — | — | TEOS | 96 | 13.9 | 4.3 | 0.6 | 1.5 | 76.5 | — | — | ◯ | ◯ |
| Comparative | HMDS | 4 | — | — | PGMEA | 96 | 15.6 | 5.6 | 9.8 | 1.1 | 49.3 | — | — | X | ◯ |
| Example 2 | | | | | | | | | | | | | | | |
| Comparative | HMDS | 4 | — | — | n-octanol | 96 | 16.0 | 5.0 | 11.2 | 1.6 | <10.0 | <10.0 | <10.0 | ◯ | X |
| Example 3 | | | | | | | | | | | | | | | |
| Comparative | TMSDMA | 4 | — | — | PGMEA | 96 | 15.6 | 5.6 | 9.8 | 1.1 | 80.0 | — | — | X | ◯ |
| Example 4 | | | | | | | | | | | | | | | |

TABLE 2

| | | | nitrogen- | | | | | | | | | | | | |
|---|---|---|---|---|---|---|---|---|---|---|---|---|---|---|---|
| | | | containing | | | | | | | | contact angle | | | | reactivity |
| | silylating | | heterocyclic | | | | Hansen | | | | of water after | | | resistance | between |
| | agent | | compound | | solvent | | solubility | | | | surface | | | of | silylating |
| | | % by | | % by | | % by | parameters | | | | treatment (°) | | | polyvinyl | agent and |
| | type | mass | type | mass | type | mass | dD | dP | dH | RED | Si | SiN | ThOx | chloride | solvent |
| Example 13 | HMDS | 5 | 1,2,4- | 0.05 | DEDMS/ | 94.95 | 14.1 | 2.8 | 3.1 | 1.3 | 52.9 | 32.2 | 49.6 | ◯ | ◯ |
| | | | triazole | | PGMEA = | | | | | | | | | | |
| | | | | | 95/5 | | | | | | | | | | |
| Example 14 | HMDS | 5 | BTA | 1 | TEOS | 94 | 13.9 | 4.3 | 0.6 | 1.5 | 88.2 | 62.0 | 87.3 | ◯ | ◯ |
| Example 15 | HMDS | 5 | BTA | 1 | DEDMS | 94 | 14.0 | 2.6 | 2.7 | 1.3 | 91.4 | 63.3 | 91.1 | ◯ | ◯ |
| Example 16 | HMDS | 5 | BTA | 1 | DIAE/ | 94 | 15.2 | 2.4 | 2.8 | 1.2 | 89.5 | 60.3 | 89.2 | ◯ | ◯ |
| | | | | | PGMEA = | | | | | | | | | | |
| | | | | | 95/5 | | | | | | | | | | |
| Example 17 | TMSDMA | 5 | — | — | MTES | 95 | 14.2 | 2.8 | 2.8 | 1.2 | 75.4 | 45.0 | 73.2 | ◯ | ◯ |
| Comparative | HMDS | 5 | BTA | 1 | DEGEA | 94 | 16.2 | 5.1 | 9.2 | 1.2 | 88.8 | 60.8 | 85.5 | X | ◯ |
| Example 5 | | | | | | | | | | | | | | | |
| Comparative | HMDS | 5 | BTA | 1 | CHAX | 94 | 16.9 | 3.8 | 5.3 | 1.1 | 89.0 | 62.0 | 85.7 | X | ◯ |
| Example 6 | | | | | | | | | | | | | | | |
| Comparative | HMDS | 5 | BTA | 1 | benzyl acetate | 94 | 18.3 | 5.7 | 6.0 | 1.6 | 89.5 | 61.6 | 89.3 | X | ◯ |
| Example 7 | | | | | | | | | | | | | | | |
| Comparative | TMSDMA | 5 | 1,2,4- | 0.5 | CHAX | 94.5 | 16.9 | 3.8 | 5.3 | 1.1 | 85.5 | 64.5 | 85.3 | X | ◯ |
| Example 8 | | | triazole | | | | | | | | | | | | |
| Example 18 | TMSDMA | 6 | 1,2,4- | 0.05 | DEDMS/ | 93.95 | 14.1 | 2.8 | 3.1 | 1.3 | 86.9 | 60.9 | 85.4 | ◯ | ◯ |
| | | | triazole | | PGMEA = | | | | | | | | | | |
| | | | | | 95/5 | | | | | | | | | | |
| Example 19 | TMSDMA | 6 | BTA | 1 | DIAE/ | 93 | 15.2 | 2.6 | 3.2 | 1.2 | 85.8 | 60.7 | 85.3 | ◯ | ◯ |
| | | | | | PGMEA = | | | | | | | | | | |
| | | | | | 89/11 | | | | | | | | | | |
| Example 20 | TMSDMA | 6 | — | — | n-decane | 94 | 15.7 | 0.0 | 0.0 | 2.0 | 85.4 | 48.2 | 81.0 | ◯ | ◯ |
| Comparative | HMDS | 6 | BTA | 1 | MIBC | 93 | 15.4 | 3.3 | 12.3 | 2.0 | <10.0 | <10.0 | <10.0 | ◯ | X |
| Example 9 | | | | | | | | | | | | | | | |
| Comparative | TMSDMA | 6 | — | — | PGMEA | 94 | 15.6 | 5.6 | 9.8 | 1.1 | 81.5 | 42.0 | 78.1 | X | ◯ |
| Example 10 | | | | | | | | | | | | | | | |
| Comparative | TMSDMA | 6 | — | — | CHAX | 94 | 16.9 | 3.8 | 5.3 | 1.1 | 75.6 | 40.0 | 69.8 | X | ◯ |
| Example 11 | | | | | | | | | | | | | | | |
| Example 21 | HMDS | 7 | 1,2,4- | 0.05 | TEOS | 92.95 | 13.9 | 4.3 | 0.6 | 1.5 | 60.4 | 37.3 | 57.5 | ◯ | ◯ |
| | | | triazole | | | | | | | | | | | | |
| Comparative | HMDS | 7 | 1,2,4- | 0.05 | PGMEA | 92.95 | 15.6 | 5.6 | 9.8 | 1.1 | 52.7 | 35.6 | 43.5 | X | ◯ |
| Example 12 | | | triazole | | | | | | | | | | | | |
| Comparative | HMDS | 7 | BTA | 1 | PGMEA | 92 | 15.6 | 5.6 | 9.8 | 1.1 | 89.8 | 62.5 | 87.1 | X | ◯ |
| Example 13 | | | | | | | | | | | | | | | |
| Comparative | HMDS | 7 | BTA | 1 | n-octanol | 92 | 16.0 | 5.0 | 11.2 | 1.6 | <10.0 | <10.0 | <10.0 | ◯ | X |
| Example 14 | | | | | | | | | | | | | | | |
| Comparative | HMDS | 7 | — | — | n-octanol | 93 | 16.0 | 5.0 | 11.2 | 1.6 | <10.0 | <10.0 | <10.0 | ◯ | X |
| Example 15 | | | | | | | | | | | | | | | |
| Example 22 | HMDS | 10 | imidazole | 0.05 | n-decane | 89.95 | 15.7 | 0.0 | 0.0 | 2.0 | 50.9 | 27.6 | 53.0 | ◯ | ◯ |

As is apparent from Table 1 and Table 2, the surface treatment liquids of Examples 1 to 22 in which the solvent does not have a hydroxyl group bonded to a carbon atom and satisfies the both conditions: (i) a value of dH in Hansen solubility parameters of the solvent (S) is 3.2 MPa^{1/2} or less or 10.5 MPa^{1/2} or more, (ii) Relative Energy Difference (RED) of a solvent and polyvinyl chloride is 1.2 or more, do not deteriorate polyvinyl chloride and can hydrophobize (silylate) the surface of treatment target.

On the contrary, the surface treatment liquids of Comparative Examples 1, 2, 4 to 8, 10 to 13, in which the solvent does not have a hydroxyl group bonded to a carbon atom but at least one of the above-mentioned conditions (i) and (ii) is not satisfied, deteriorated polyvinyl chloride. Furthermore, in the surface treatment liquids of Comparative Examples 3, 9, 14, and 15 in which the solvent includes a hydroxyl group bonded to a carbon atom, a silylating agent and a solvent are reacted with each other. The surface of the treatment target cannot be hydrophobized (silylated).

What is claimed is:

1. A surface treatment method that treats a surface of a treatment target using a device having a liquid contact portion provided with a member made of polyvinyl chloride, the method comprising:
bringing a surface treatment liquid into contact with the surface of the treatment target,
wherein the surface treatment liquid includes a silylating agent (A) and a solvent (S),
the silylating agent (A) does not have an alkoxy group bonded to a silicon atom,
the solvent (S) does not have a hydroxyl group bonded to a carbon atom,
a value of dH in Hansen solubility parameters of the solvent (S) is 3.2 MPa^{1/2} or less or 10.5 MPa^{1/2} or more, and
Relative Energy Difference represented by Rₐ/R₀ is 1.2 or more, where an interaction radius of the polyvinyl chloride in a Hansen space is defined as R₀, and a distance between Hansen solubility parameters of the polyvinyl chloride and Hansen solubility parameters of the solvent (S) is defined as Rₐ.

2. The surface treatment method according to claim 1, wherein the solvent (S) includes one or more selected from aliphatic hydrocarbon, an alkoxysilane compound represented by the following Formula (S1):
SiR^{s1}₍₄₋ₐ₎R^{s2}ₐ (S1)
wherein in the Formula (S1), R^{s1} represents an alkoxy group having 1 to 4 carbon atoms, R^{s2} represents an alkyl group having 1 to 4 carbon atoms, and a is an integer of 0 to 3, and dialkyl ether.

3. The surface treatment method according to claim 1, wherein the surface treatment liquid further comprises a nitrogen-containing heterocyclic compound (B) that does not include a silicon atom.

4. A surface treatment liquid used in surface treatment of a treatment target,
comprising:
a silylating agent (A); and
a solvent (S),
wherein the silylating agent (A) does not have an alkoxy group bonded to a silicon atom,
the solvent (S) does not have a hydroxyl group bonded to a carbon atom, and includes an alkoxysilane compound represented by the following Formula (S1):
SiR^{s1}₍₄₋ₐ₎R^{s2}ₐ (S1)
wherein in the Formula (S1), R^{s1} represents an alkoxy group having 1 to 4 carbon atoms, R^{s2} represents an alkyl group having 1 to 4 carbon atoms, and a represents an integer of 0 to 3.

5. The surface treatment liquid according to claim 4, further comprising a nitrogen-containing heterocyclic compound (B) that does not include a silicon atom.

6. A surface treatment method that treats a surface of a treatment target,
the method comprising:
bringing a surface treatment liquid into contact with a surface of the treatment target,
wherein the surface treatment liquid includes a silylating agent (A) and a solvent (S),
the silylating agent (A) does not have an alkoxy group bonded to a silicon atom,
the solvent (S) does not have a hydroxyl group bonded to a carbon atom, and includes an alkoxysilane compound represented by the following Formula (S1):
SiR^{s1}₍₄₋ₐ₎R^{s2}ₐ (S1)
wherein in the Formula (S1), R^{s1} represents an alkoxy group having 1 to 4 carbon atoms, R^{s2} represents an alkyl group having 1 to 4 carbon atoms, and a represents an integer of 0 to 3.

7. The surface treatment method according to claim 6, wherein the surface treatment liquid further comprises a nitrogen-containing heterocyclic compound (B) that does not include a silicon atom.
